(19) United States
(12) Patent Application Publication
(10) Pub. No.: US 2009/0241332 A1
(43) Pub. Date: Oct. 1, 2009

(54) Circuitized substrate and method of making same

(76) Inventors: John M. Lauffer, Waverly, NY (US); Roy H. Magnuson, Endicott, NY (US); Voya R. Markovich, Endwell, NY (US); James P. Paoletti, Endwell, NY (US); Kostas I. Papathomas, Endicott, NY (US); Rajinder S. Rai, Vestal, NY (US)

Correspondence Address: Mark Levy;HINMAN, HOWARD & KATTELL, LLP, 80 Exchange Street, P.O. Box 5250, BINGHAMTON, NY, 13901, US

(21) Appl. No.: 12/078,206

(22) Filed: Mar. 28, 2008

(51) Int. Cl. H05K 3/00

(52) U.S. Cl. 29/829

(57) ABSTRACT

A circuitized substrate and method of making same in which a first plurality of holes are formed within two bonded dielectric layers and then made conductive, e.g., plated. The substrate also includes third and fourth dielectric layers bonded to the first and second with a plurality of continuous electrically conductive thru holes extending through all four dielectric layers. Conductive paste is positioned within the thru holes for providing electrical connections between desired conductive layers of the substrate and outer layers as well. A circuitized substrate assembly and method of making same are also provided.

### TECHNICAL FIELD

The present invention relates to circuitized substrates, and more particularly to multilayered circuitized structures such as printed circuit boards (PCBs) and chip carriers. The present invention also relates to methods for fabricating such structures.

### BACKGROUND OF THE INVENTION

A common method of forming a multi-layered circuitized substrate involves forming sub-composites each including an individual layer of dielectric material and a layer of electrically conducting material thereon, and then forming electrical circuit patterns in the electrically conductive layer. The conducting material, typically copper, provides signal and voltage planes, as needed. The signal planes are typically in discrete wiring patterns. Voltage planes can be either ground or power planes, and are sometimes collectively referred to as power planes. If required, thru holes are formed within this sub-composite structure by drilling or etching. This method relies on each successive step of adding additional dielectric layers and then forming circuitry thereon, until the desired number of conductive planes has been formed. Thru holes may be formed upon completion of each of these successive steps, and it is also possible to form thru holes through the entire thickness of the final multilayered composite. This requires precise drilling to form the holes at each step (if desired) in addition to the final hole formation step if holes extend through the entire thickness.

As defined herein, the invention relates particularly to “high speed” circuitized substrates. By the term “high speed” as used in this manner is understood to mean signals within a frequency range of from about 3.0 to about 10.0 gigabits per second (GPS) and possibly even faster. The use of appropriately thick dielectric and conductive layers is especially important with respect to such substrate products. With operational requirements increasing for complex electronic components such as semiconductor chips which are mounted on circuitized substrates or within chip carriers which in turn are mounted on such substrates, so too must the host substrate be capable of handling these increased requirements. One particular increased requirement has been the need for higher frequency (high speed) connections between two or more such mounted components, which connections, as stated, occur through the underlying host substrate. Such high speed connections are subjected to various detrimental effects, e.g., signal deterioration (also referred to as signal attenuation), caused by the inherent characteristics of such known substrate circuitry wiring. In the particular case of signal deterioration, this effect is expressed in terms of either the “rise time” or the “fall time” of the signal's response to a step change. The deterioration of the signal can be quantified with the formula (Z₀ C)/2, where Z₀ is the transmission line characteristic impedance, and C is the amount of the connecting thru-hole capacitance (the thru-hole typically being plated with metal and/or including conductive paste therein). In a signal line (also referred to in the industry as a wire or trace) having a typical 50 ohm transmission line impedance, a plated thru hole having a capacitance of 4 pico-farads (pf) would represent a 100 pico-second (ps) rise-time (or fall time) degradation. This compares to a 12.5 ps degradation with a 0.5 pf “buried via” type of thru hole. This difference is significant in systems which operate at 800 MHz or faster (becoming the “norm” in today's technical world), where there are associated signal transition rates of 200 ps or faster.

The teachings of the present invention are not limited to the manufacture of high speed substrates such as PCBs and the like, however, but are also applicable to the manufacture of substrates used for other purposes than high speed signal connections. Generally speaking, the teachings herein are applicable to any such substrates in which one or more conductive layers such as copper are bonded (e.g., laminated) to an adjacent dielectric layer and the resulting composite then used as the substrate, typically when combined with other dielectric and conductive layers to form a much thicker, built-up structure. The invention is able to provide a final structure in which signal attenuation is reduced while still assuring effective conductive layer and dielectric layer adhesion.

The following patents, some of which are assigned to the same Assignee as the present invention, Endicott Interconnect Technologies, Inc., define various multilayered circuitized substrate structures and methods of making same, including those possessing high speed capabilities. The listing of these is not an admission that any is prior art to the present invention.

In U.S. Pat. No. 6,388,204, there is described a laminate circuit structure assembly that comprises what are described as modularized circuitized plane subassemblies, and a joining layer located between each of the subassemblies wherein the subassemblies and joining layer are bonded together with a cured dielectric from a bondable, curable dielectric. The subassemblies and joining layer are electrically interconnected with bondable electrically conductive material. The joining layer comprises dielectric layers disposed about an internal electrically conductive layer. The electrically conductive layer has a via (a conductive hole) and the dielectric layers each have a via of smaller diameter than the vias in the electrically conductive layer and are aligned with the vias in the electrically conductive layer. The vias are filled with electrically bondable electrically conductive material for providing electrical contact between the subassemblies.

In U.S. Pat. No. 6,465,084, there is described a method of forming a core for and forming a composite wiring board. The core has an electrically conductive coating on at least one face thereof. At least one opening is formed through the structure extending from one face to the other and through each conductive coating. An electrically conductive material is dispensed in each of the openings extending through the conducting coating. At least a portion of the surface of the conductive coating on one face is removed to allow a nub of the conductive material to extend above the substrate face and any remaining conductive material to thereby form a core that can be electrically joined face-to-face with a second core member or other circuitized structure.

In U.S. Pat. No. 6,479,093, there is described a method of making the laminate circuit structure assembly of U.S. Pat. No. 6,388,204 (U.S. Pat. No. 6,479,093 is a divisional application of U.S. Pat. No. 6,388,204).

In U.S. Pat. No. 6,504,111, there is described a structure for interconnecting between layers of a multilayer circuit board. The structure comprises a stack that includes at least one layer and a via (hole) opening that extends through at least one layer of the stack. Each individual via opening is filled with a solid conductive plug and each solid conductive plug has a first contact pad and a second contact pad.

In U.S. Pat. No. 6,570,102, there is described a method and arrangement for creating an impedance controlled printing wiring board, particularly the formation of a structure for high speed printed wiring boards incorporating multiple differential impedance controlled layers. This patent further describes providing holes which are filled with a conductive paste material to form electrical interconnections with conductive layers of the printed wiring board.

In U.S. Pat. No. 6,593,534, there is described a structure of and method for producing a multilayer printed or wiring circuit board, and more particularly a method producing so-called “z-axis” or multilayer electrical interconnections in a hierarchical wiring structure in order to be able to provide for an increase in the number of inputs and outputs in comparison with a standard printed circuit board arrangement.

In U.S. Pat. No. 6,634,543, there is described the deterioration and damage to insulator materials in an interconnection structure having vertical connections which is avoided by performing diffusion bonding of metal pads at plated through holes (PTHs) at temperatures below the melting points of conductive material in the bond. Diffusion bonding is achieved during time periods required for processing (e.g. curing or drying) of insulating materials in the laminated structure.

In U.S. Pat. No. 6,638,607, there is described a method of forming a composite wiring board, using a “member.” The member includes a dielectric substrate. Adhesive tape is applied to at least one face of this substrate and at least one opening is formed through the substrate extending from one face to the other and through each adhesive tape. An electrically conductive material is dispensed in each of the openings and partially cured. The adhesive tape is removed to allow a nub of the conductive material to extend above the substrate face to form a wiring structure with other elements.

In U.S. Pat. No. 6,645,607, there is described a method of forming a “core” for use as part of a composite wiring board. The core has an electrically conductive coating on at least one face of a dielectric substrate. At least one opening is formed through the substrate extending from one face to the other and through each conductive coating. An electrically conductive material is dispensed in each of the openings extending through the conducting coating. At least a portion of the surface of the conductive coating on one face is removed to allow a nub of the conductive material to extend above the substrate face and any remaining conductive material to thereby form a core that can be electrically joined face-to-face with a second core member or other circuitized structure.

In U.S. Pat. No. 6,790,305, there is described a method for producing small pitch “z-axis” electrical interconnections in layers of dielectric materials which are applied to printed wiring boards and diverse electronic packages. In this method, parallel fabrication of intermediate structures occurs such that the structures are subsequently jointed to form a final structure. In addition, there is provided a “z-interconnected” electrical structure, employing dielectric materials such as resin coated copper, employable in the manufacture of diverse type of electronic packages, including printed circuit boards, multi-chip modules and the like.

In U.S. Pat. No. 6,809,269, there is described a circuitized substrate assembly and method for making same wherein the assembly includes individual circuitized substrates bonded together. The substrates each include at least one opening, only one of which is substantially filled with a conductive paste prior to bonding. Once bonded, the paste is also partially located within the other opening to provide an effective electrical connection therewith. This method of forming such a structure is also referred to as a “z-interconnect” method.

In U.S. Pat. No. 6,826,830, there is described a multi-layered interconnect structure and method of formation. In a first embodiment, first and second liquid crystal polymer dielectric layers are directly bonded, respectively, to first and second opposing surface of a thermally conductive layer, with no extrinsic adhesive material bonding the thermally conductive layer with either the first or second dielectric layer. In a second embodiment, first and second substructures are directly bonded, respectively, to first and second opposing surfaces of a dielectric joining layer, with no extrinsic adhesive material bonding the dielectric joining layer with either the first or second substructures.

In U.S. Pat. No. 6,872,894, there is described an information handling system (e.g., computer, server, etc.) utilizing at least one circuitized substrate assembly of robust construction and possessing enhanced operational capabilities. The substrate assemblies include a substrate having at least one opening which is substantially filled with a conductive paste prior to bonding. Once bonded, the paste is also partially located within the other opening to provide an effective electrical connection therewith.

In U.S. Pat. No. 6,900,392, a divisional application of U.S. Pat. No. 6,872,894, there is also described an information handling system (e.g., computer, server, etc.) utilizing at least one circuitized substrate assembly of robust construction and possessing enhanced operational capabilities. The substrate assemblies include a substrate having at least one opening which is substantially filled with a conductive paste prior to bonding. Once bonded, the paste is also partially located within the other opening to provide an effective electrical connection therewith.

In U.S. Pat. No. 6,955,849, there is described a method for producing small pitch z-axis electrical interconnections in layers of dielectric materials which are applied to printed circuit boards and other electronic packages. A method for parallel fabrication of intermediate structures which are subsequently jointed to form a final structure is also discussed. In addition, there is provided a z-interconnected electrical structure, employing dielectric materials such as resin coated copper, employable in the manufacture of diverse type of electronic packages, including PCBs, multi-chip modules and the like.

In U.S. Pat. No. 6,969,436, there is described a method of forming a member for joining to a composite wiring board. The member includes a dielectric substrate. Adhesive tape is applied to at least one face of said substrate. At least one opening is formed through the substrate extending from one face to the other and through each adhesive tape. An electrically conductive material is dispensed in each of the openings and partially cured. The adhesive tape is removed to allow a nub of the conductive material to extend above the substrate face to form a wiring structure with other elements.

In U.S. Pat. No. 6,995,322, there is described a circuitized substrate including a plurality of conductive and dielectric layers and also a plurality of conductive thru-holes therein for passing high speed signals, e.g., from one component to another mounted on the substrate. The substrate utilizes a signal routing pattern which uses the maximum length of each of the thru-holes wherever possible to thereby substantially eliminate signal loss (noise) due to thru-hole “stub” resonance. A multilayered circuitized substrate assembly using more than one circuitized substrate, an electrical assembly using a circuitized substrate and one or more electrical components, a method of making the circuitized substrate and an information handling system incorporating one or more circuitized substrate assemblies and attached components are also provided.

In U.S. Pat. No. 7,047,630, there is described a circuitized substrate assembly and method for making same wherein the assembly includes individual circuitized substrates bonded together. The substrates each include at least one opening, only one of which is substantially filled with a conductive paste prior to bonding. Once bonded, the paste is also partially located within the other opening to provide an effective electrical connection therewith.

In U.S. Pat. No. 7,071,423, there is described a circuitized substrate assembly and method for making same wherein the assembly includes individual circuitized substrates bonded together. The substrates each include at least one opening, only one of which is substantially filled with a conductive paste prior to bonding. Once bonded, the paste is also partially located within the other opening to provide an effective electrical connection therewith. This method may also be referred to as a “z-interconnect” method of forming a multilayered PCB or other substrate.

In U.S. Pat. No. 7,076,869, there is described a method for providing an interconnect structure for use between layers of a multilayer circuit board. A first via (hole) extending through a total thickness of a first layer is formed. The first via is totally filled with a first solid conductive plug and an end of the first solid conductive plug includes a first contact pad that is in contact with a surface of the first layer. A second via extending through a total thickness of a second layer is formed. The second via totally filling with a second solid conductive plug and an end of the second solid conductive plug includes a second contact pad that is in contact with a surface of the second layer. The second layer is electrically and mechanically coupled to the first layer by an electrically conductive adhesive that is in electrical and mechanical contact with both the end of the first plug and the end of the second plug.

In U.S. Patent Publication 2007/0006452, there is described a method of making a circuitized substrate which includes a high temperature dielectric material in combination with a low temperature conductive paste, the paste including an organic binder component and at least one metallic component. The flakes of the metallic component are sintered to form a conductive path through the dielectric when the dielectric is used as a layer in the substrate.

In U.S. Patent Publication 2007/0007033, there is described a circuitized substrate which includes a conductive paste for providing electrical connections. The paste, in one embodiment, includes a binder component and at least one metallic component including micro particles. In another embodiment, the paste includes the binder and a plurality of nano-wires. Selected ones of the micro particles or nano-wires include a layer of solder thereon. A method of making such a substrate is also provided, as are an electrical assembly and information handling system adapter for having such a substrate as part thereof.

U.S. Pat. Nos. 6,809,269, 6,872,894, 6,900,392, 6,995,322, 7,047,630, 7,071,423, and the inventions defined in U.S. Patent Publications 2007/0006452 and 2007/0007033 are assigned to the same Assignee as the present invention and the teachings of these documents are incorporated herein by reference.

The present invention represents an improvement over methods such as described in the foregoing and otherwise known in the art by teaching the use of relatively thin dielectric layer(s) as part of a circuitized substrate capable of forming a “core” (interconnecting) structure between other substrates as part of a larger multilayered circuitized substrate. Thru-holes in this substrate are shorter than normal such that conductive paste positioned therein as a conductive material between desired conductive levels in the final structure will be less resistive than if of a longer length. It is believed that an invention possessing such properties as well as others defined herein or discernible from the teachings herein will constitute a significant advancement in the art.

### OBJECTS AND SUMMARY OF THE INVENTION

It is a primary object of the present invention to enhance the circuitized substrate art.

It is another object of the invention to provide a method of making a circuitized substrate which will possess the many advantageous features defined herein and otherwise discernible from the instant teachings.

It is still another object of the invention to provide such a method which may be accomplished in a relatively facile manner and at relatively low cost in comparison to some known substrate manufacturing processes.

According to one aspect of the invention, there is provided a method of making a circuitized substrate comprising providing a first dielectric layer having a first thickness, forming a conductive circuit on this first dielectric layer, bonding a second dielectric layer having a second thickness to the first dielectric layer such that the first and second dielectric layers will have a combined, third thickness, forming a first plurality of holes within the first and second dielectric layers, this first plurality of holes extending through both first and second dielectric layers, bonding third and fourth dielectric layers to the first and second dielectric layers, respectively, forming a second plurality of holes within each of these third and fourth dielectric layers, each of this second plurality of holes being in alignment with a respective one of the first plurality of holes to thereby form a plurality of continuous holes through the first, second, third and fourth dielectric layers, and positioning a quantity of conductive paste within each of these continuous holes to thereby form a plurality of continuous thru-holes each having a length such that the conductive paste within each of these thru-holes will possess a relatively low resistivity.

According to another aspect of this invention, there is provided a circuitized substrate comprising a first dielectric layer having a first thickness, a conductive circuit on this first dielectric layer, a second dielectric layer having a second thickness bonded to the first dielectric layer such that said second dielectric layer substantially covers said conductive circuit, a first plurality of holes extending through the first and second dielectric layers and including an electrically conductive layer thereon, third and fourth dielectric layers bonded to the first and second dielectric layers, respectively, a plurality of continuous thru holes extending through the first, second third and fourth dielectric layers, each of these plurality of continuous thru holes being in alignment with a respective one of the first plurality of holes within the first and second dielectric layers and including a quantity of electrically conductive paste therein, this electrically conductive paste possessing a relatively low resistivity.

### BRIEF DESCRIPTION OF THE DRAWINGS

FIGS. 1-10 are side elevational views, in section, illustrating the various steps of making a circuitized substrate in accordance with one embodiment of the invention; and

FIG. 11 is a side-elevational view, in section, illustrating a circuitized substrate assembly including the circuitized substrate of FIG. 10 as part thereof.

### BEST MODE FOR CARRYING OUT THE INVENTION

For a better understanding of the present invention, together with other and further objects, advantages and capabilities thereof, reference is made to the following disclosure and appended claims in connection with the above-described drawings. It is understood that like numerals will be used to indicate like elements from drawing figure to drawing figure.

The following terms will be used herein and are understood to have the meanings associated therewith.

By the term “circuitized substrate” is meant to include substrates including at least one and preferably more dielectric layers and at least one and preferably more conductive layers therein/thereon. Examples of dielectric materials suitable for use herein include fiberglass-reinforced or non-reinforced epoxy resins, polytetrafluoroethylene (Teflon), polyimides, polyamides, cyanate resins, photoimageable materials, ceramic and other like materials, or combinations thereof. Examples of materials for the conductive layer include copper or copper alloy, and the layer may form a power or signal plane. If the dielectric is a photoimageable material, it is photoimaged or photopatterned, and developed to reveal the desired circuit pattern, including the desired opening(s) as defined herein, if required. The dielectric material may be curtain coated or screen applied, or it may be supplied as a dry film or in other sheet form.

By the term “circuitized substrate assembly” as used herein is meant to include at least two of such circuitized substrates in a bonded configuration, one example of bonding being conventional lamination procedures known in the art. One example of such an assembly is a multilayered PCB which includes several dielectric and conductive layers, with the conductive layers formed in an alternating manner relative to the dielectric layers.

By the term “electrically conductive paste” as used herein is meant to include a bondable (e.g., capable of lamination) conductive material capable of being dispensed within openings of the type taught herein. Typical examples of bondable electrically conductive material are conductive pastes such as silver filled epoxy paste obtained from E.I. duPont deNemours under the trade designation “CB-100”, Ablebond “8175” from the Ablestik National Starch & Chemical Company, and filled polymeric systems (thermoset or thermoplastic type), containing transient liquid conductive particles or other metal particles such as gold, tin, palladium, copper, alloys, and combinations thereof. One particular example is coated copper paste. Metal coated polymeric particles disposed in a polymeric matrix can also be used.

By the term “electrical component” as used herein is meant components such as semiconductor chips, resistors, capacitors and the like, which are adapted for being positioned on the external conductive surfaces of such substrates as PCBs and chip carriers, and possibly electrically coupled to other components, as well as to each other, using, for example the PCBs or chip carrier's internal and/or external circuitry. The circuitized substrates and substrate assemblies formed in accordance with the teachings herein are readily adaptable for having one or more such electrical components positioned thereon and electrically coupled to the internal circuitry thereof, as well as to each other if so desired.

As mentioned above, by the term “high speed” as used herein to define the substrate signal speed capabilities is understood to mean signals within a frequency range of from about 3.0 to about 10.0 gigabits per second (GPS) and possibly even faster.

By the term “sticker sheet” as used herein is meant to include dielectric materials such as conventional prepreg materials used in conventional, multilayered PCB construction, e.g., usually by lamination. Other examples include the products Pyralux and liquid crystal polymer (LCP) or other freestanding films. As defined herein, these dielectric sticker sheets may be adhesively applied to one or both of the two circuitized substrates to assist in bonding these two components. These sheets may also be patterned, e.g., by laser or photoimaging, if desired. Such sticker sheets may be typically 1 to 8 mils (thousandths of an inch) thick.

By the term “thru hole” as used herein is meant to include three different types of electrically conductive holes formed with a circuitized substrate or circuitized substrate assembly. As mentioned, it is known in multilayer printed circuit boards to provide various conductive interconnections between the various conductive layers of the board. For some applications, it is desired that electrical connection be made with almost if not all of the conductive layers. In such a case, thru-holes are typically provided through the entire thickness of the board, in which case these are often also referred to as “plated thru holes” or PTHs. For other applications, it is often desired to also provide electrical connection between the circuitry on one face of the board to a depth of only one or more of the inner circuit layers. These are referred to as “blind vias”, which pass only part way through (into) the board. In still another case, such multilayered boards often require internal “vias” which are located entirely within the board's structure and covered by external layering, including both dielectric and conductive. Such internal “vias”, also referred to as “buried vias”, are typically formed within a first circuitized substrate which is then bonded to other substrates and/or dielectric and/or conductive layers to form the final board. Therefore, for purposes of this application, the term “thru hole” is meant to include all three types of such electrically conductive openings.

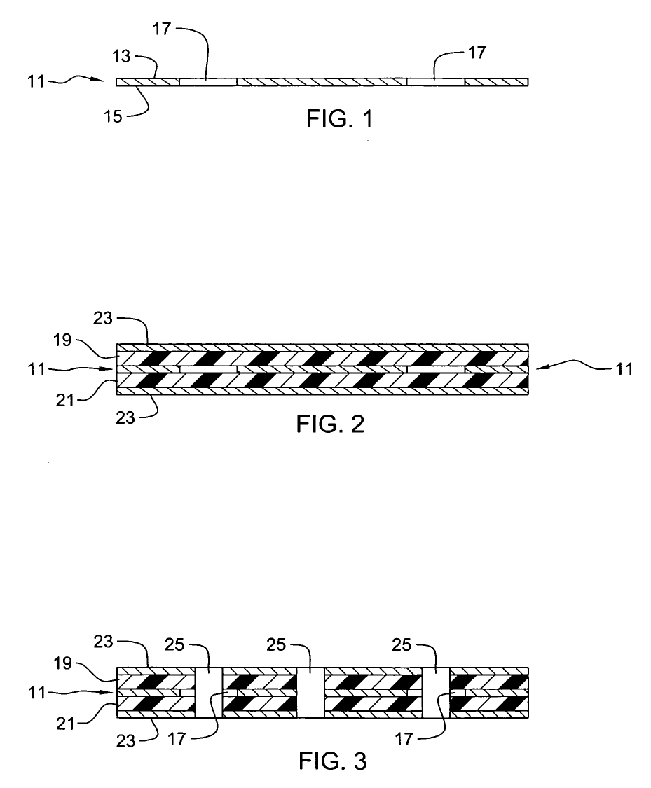

In FIG. 1, a foil 11 of electrically conductive material, preferably “standard” or “plain and stable” electrodeposited copper foil, is provided. In this form, foil 11 includes first and second opposing sides 13 and 15, respectively, and in one embodiment, has a thickness within the range of from about 1 mil to about 3 mils (a mil understood to be 1/1000 of an inch). If an electrodeposited copper foil, side 13 may be the “drum” side (meaning it was formed against the drum surface during the electroplating) and in turn may include an RMS (Root Mean Square) roughness value of about 0.1 to about 0.5 microns. The maximum peak-to-valley roughness (hereinafter PTV roughness) value for this side is preferably from about 1.0 micron to about 2.0 microns with an optimal value being 1.5 microns. Opposite side 15, if of the same foil material, may represent the “matte” side (meaning it was not against the drum during electroplating). As such, this side may be rougher than side 13 and, in this same example, may possess an initial roughness using the same RMS standard of about 1.0 to about 3.0 microns with a maximum PTV roughness from about 2.5 to about 10.0 microns. By the term “plain and stable” when defining electrodeposited copper foil is meant a copper foil which has not received additional surface roughening treatment (e.g. a secondary nodular plating), but may have been given a known chemical anti-stain treatment. By the term “standard” when defining electrodeposited copper foil is meant a copper foil that may have received additional roughening treatment (e.g. a secondary nodular plating) to the matte surface, and has additionally received a chemical anti-stain treatment to both surfaces. Either type of such foils is well adapted for use in the present invention, as are others known in the art.

Foil 11 is initially provided in solid form. Accordingly, it is now desirable to form openings 17 therein, which, in one embodiment of this invention, will serve as “clearance” openings when the foil is used as a conductive layer in the substrate structure. Openings 17 may be formed using conventional mechanical or laser drilling, or with conventional photolithographic processing. In this embodiment, openings 17 may possess a diameter of from about six mils to about thirty mils, these holes also being substantially cylindrical when viewed from above the foil. A total of 50,000 or more openings 17 may be formed, depending of course on the overall final size of the substrate utilizing this conductive member and the number of thru holes which are eventually formed and utilized therein. More of this is provided below.

In FIG. 2, foil 11 is shown as having two dielectric layers 19 and 21 of the material defined above (preferably a low dielectric constant (Dk) and low loss (Df) material) bonded thereto, each layer being bonded to one of the opposing sides 13 and 15. By the term “low dielectric constant” is meant a material having a dielectric constant from about 2.0 to about 3.5, while by the term ‘low Df’ is meant a material having a dielectric loss factor of less than about 0.010. A preferred means of accomplishing this is to laminate the dielectric layers using conventional PCB lamination processing. Layers 19 and 21 are preferably initially from about two mils to ten mils thick and are laminated at pressures from about 300 pounds per square in (PSI) to about 750 PSI, at temperatures within the range of about 180 degrees Celsius (C) to about 250 degrees C. As a result of the lamination, the interim foil having both dielectric layers bonded there-to, will possess an overall thickness from about five mils to about twenty-five mils. Each of the dielectric layers will in turn have a thickness from about two mils to about ten mils. Significantly, the thickness of each dielectric layer is not sufficient to achieve a desired impedance level for signals passing along conductive layers (e.g., a circuit layer having several individual lines (or traces) in a pre-defined pattern) bonded immediately thereto. This is an important aspect of this invention, as will be better understood from the following description. Layers 19 and 21 are also in a fully cured state at this stage, the above temperatures and pressures sufficient to cause such full cure.

As also seen in FIG. 2, each of the dielectric layers includes a conductive layer 23 thereon. Layers 23 are each preferably of the same copper foil material as foil 11, which now forms an internal conductive layer for the FIG. 2 structure. Each layer 23 also may have a thickness of from about 0.5 mils to 2 mils, and, as shown, is of substantially solid construction at this step in the process. These layers, like layer 11, may eventually be signal, power or ground layers in the final circuitized substrate of this invention. Layers 23 are preferably bonded to the respective dielectric layers prior to bonding to interim layer 11, but may be added to the dielectric layers during or after this bonding, e.g., by lamination. If laminated onto the bonded dielectric layer and interim conductive layer structure, pressures of about 300 to 750 PSI and temperatures of about 180 to 250 degrees C may be utilized. In one embodiment, the overall thickness of the FIG. 2 structure is about 20 mils. Although two dielectric layers have been described for this particular embodiment, it is possible to only use one, and bond this to only one side of the foil (conductive layer) 11. If so, only a single conductive layer 23 would be used, this of course on the single dielectric layer.

In FIG. 3, holes 25 are formed within the FIG. 2 structure, either by mechanical or laser drilling, these holes extending through the full structure thickness. These holes are preferably cylindrical and each may have diameters from about four mils to twelve mils wide. Notably, some (i.e., the outer two in FIG. 3) may pass through the previously formed “clearance” openings 17 while others (i.e., the middle opening) directly contacts and passes through the conductive layer 11. Although not shown in the drawings (for ease of illustration), openings 17 will likely include dielectric material therein, from one or both of the dielectric layers 19 and 21, as a result of the defined lamination processing to layer 11 during which the elevated temperatures and pressures used may cause the dielectric layer to soften and flow. The dielectric material is not shown in the present drawings to ease illustration of the various elements (especially the location of openings 17) of the structures depicted.

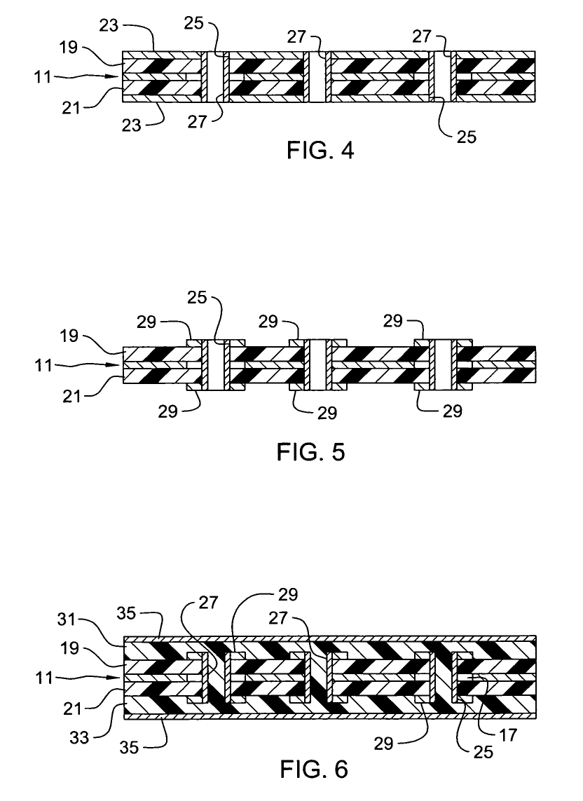

In FIG. 4, openings (holes) 25 are now plated with metallurgy to render these conductive, thus each meeting the above definition of a “thru hole.” Significantly, the plating thickness is sufficient to allow the required amount of electric current per thru hole in the final structure (below). In one embodiment, the plated metallurgy may be copper or a copper alloy, with each plated layer (27) having a thickness of from about 0.5 mils to about 1.5 mils. The preferred plating procedure is an electroless flash layer followed by electrolytically plated copper.

In FIG. 5, the outer conductive layers 23 may now be “personalized”, meaning these are circuitized to form the desired circuit pattern therein. The preferred means of accomplishing this is to use conventional photolithographic processing used in PCB manufacturing. Precise registration between the remaining conductive elements (in FIG. 5, these are “lands” 29, these being formed on opposite sides of the structure if circuitization of both conductive layers is desired, adjacent each respective plated hole) and the respective holes 25 is assured. It is also possible during this step to form other conductive elements, including the aforementioned signal lines, in addition to lands 29. Such added elements are not shown here, however, for ease of illustration.

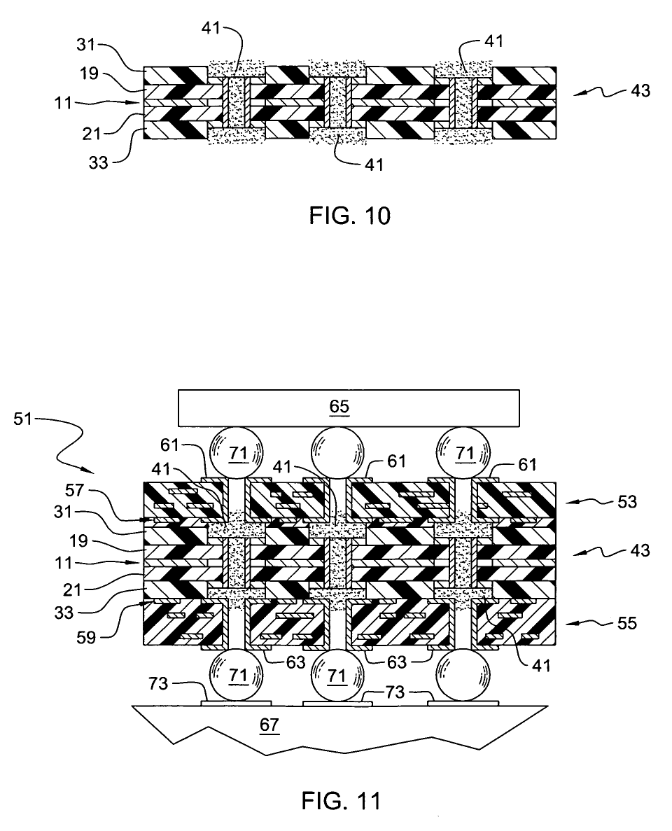

In FIG. 6, two dielectric layers 31 and 33, each also preferably of the material defined above (including preferably a low dielectric constant, low loss (Df) material), are bonded to opposite (top and bottom) sides of the FIG. 5 structure. A preferred means of accomplishing this, as was used in the structure of FIG. 2, is to laminate the dielectric layers using conventional PCB lamination processing. Layers 31 and 33 are preferably initially from about 0.5 mils to 4 mils thick and are laminated at pressures from about 300 pounds per square in (PSI) to about 750 PSI, at temperatures within the range of about 80 degrees Celsius (C) to about 130 degrees C. As a result of the lamination, the dielectric layers 31 and 33 will each possess an overall thickness of from about 0.5 to 3.5 mils and, significantly, will only be at a partially cured state. One example of such a state is known in the art as “B-stage” meaning the dielectric material is still somewhat soft and movable under more intense pressure and higher temperatures. Each of the dielectric layers will in turn have a thickness of from about 0.5 to 3.5 mils. Significantly, the thickness of each dielectric layer, like that of layers 19 and 21, is not sufficient to achieve a desired impedance level for signals passing along conductive layers (e.g., a circuit layer having several individual lines (or traces) in a pre-defined pattern) bonded immediately thereto. However, the resulting (laminated) thickness of each is sufficient that it will assure such a desired impedance level when combined with the thickness of the other in the final circuitized substrate assembly structure when signals are passed along signal lines which form circuits on the conductive layers bonded to both of these dielectric layers. As defined below, the final thickness for layers 31 and 33 is not established until the final circuitized substrate (i.e., that shown in FIG. 10) is bonded to at least one other circuitized substrate to form a circuitized substrate assembly such as the one shown in FIG. 11. Until this occurs, layers 31 and 33, unlike fully cured layers 19 and 21, remain in their uncured (e.g., “B-stage”) condition. At that time (final lamination), the combined dielectric thicknesses of the four layers will assure the desired impedance between opposed conductive circuits (signal lines) on the conductive layers located on opposite sides of the four dielectric layer combination (FIG. 10). That is, the length of the conductive paste to be used in the holes through these layers will be substantially optimal for enhanced conductivity through the circuit paths in such holes, which are now of course thru holes according to the definition above.

As also seen in FIG. 6, each of the dielectric layers 31 and 33 includes a conductive layer 35 thereon. Layers 35 are each preferably of the same copper foil material as layers 23, and may have a thickness of from about 0.5 mils to two mils. As shown, each layer 35 is of substantially solid construction at this step in the process. Significantly, these layers, unlike layers 23, will not eventually be signal, power or ground layers in the final circuitized substrate of this invention, but instead will be removed, as defined below. Layers 35 are preferably bonded (e.g., laminated) to the respective dielectric layers 31 and 33 prior to bonding of these dielectric layers to the FIG. structure, but may be added to the dielectric layers during or after this bonding, e.g., by lamination. If laminated onto the bonded dielectric layer and interim conductive layer structure, pressures of about 300 to 750 PSI and temperatures of about 80 to 130 degrees C may be utilized. In one embodiment, the overall thickness of the FIG. 6 structure is now about 30 mils. As in the embodiment of FIG. 2, although two dielectric layers have been described for this particular embodiment, it is possible to only use one, and bond this to only one side of the FIG. 5 structure. If so, only a single conductive layer 35 would be used, this of course on the single bonded dielectric layer. The above bonding of the outer conductive layers does not result in fully curing of the partially cured dielectric materials of the hosting layers.

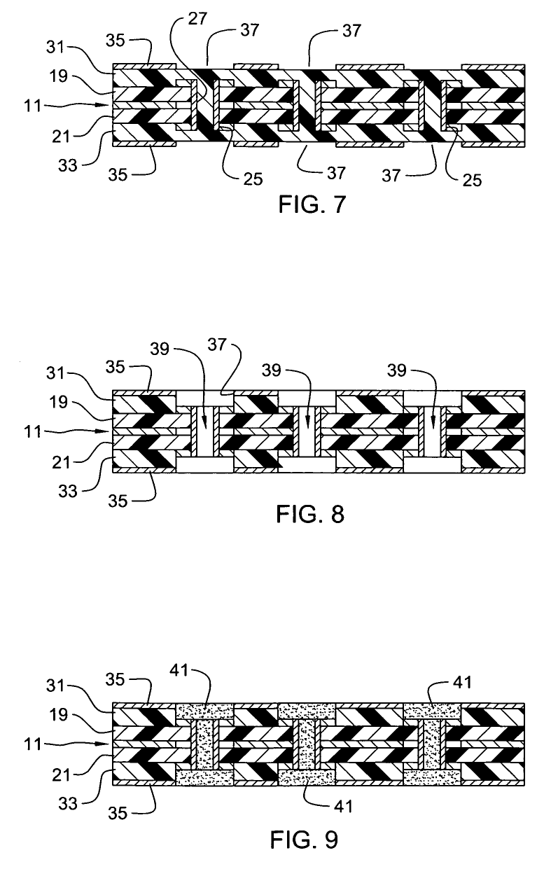

In FIG. 7, openings 37 are formed in the two conductive layers 35, each opening being in alignment with a respective hole 25. To assure precise formation in both diameter and orientation relative to the respective holes 25, laser direct imaging (LDI) is preferably utilized. In LDI, a known procedure in manufacture of PCBs, a laser is used to image a pattern directly onto a photoresist-coated base (here, layers 35), completely eliminating the production and use of a traditional photo tool. In a most common LDI implementation, the front end CAM system is used to modulate a focused laser beam that is raster scanned across the coated layers. The desired image pattern is built up line by line, analogous to the way in which an image is formed on a CRT display. After imaging is completed on one side, the structure being treated may then be flipped over and the second side imaged. Currently available LDI equipment of this type can scan panels relatively wide (e.g., as wide as 24″ or even greater) in a single pass, eliminating the need for any type of image stepping or stitching within a panel. The most obvious benefits of LDI are the time and costs savings associated with the creation, use, handling and storage of photo tools. In addition, LDI avoids any quality problems associated with film-related defects. The technique even enables unique marking or serialization of boards. LDI also delivers significantly better registration than traditional contact printing fabrication methods, and this improvement can increase process yields. In one example, each opening 37 may have a diameter of about 6 mils to about 14 mils, which in turn is about one to two mils larger than that of holes 25 including the plating 27 thereon.

In FIG. 8, a series of holes 39 are formed within the FIG. 7 structure, these holes extending through the entire thickness of the structure as shown. In a preferred embodiment, a carbon dioxide laser is used. Significantly, the holes 37 serve as masks to enable etching of the dielectric material (from layers 31 and 33) to approximately the same diameter as holes 37, while the lands of the plated holes 25 mask the laser to the extent it is only able to etch away dielectric material within the internal diameter of the plated holes 25. This laser ablation occurs from opposite sides of the FIG. 8 structure, to assure the different diameter openings formed in the outer dielectric layering compared to that of the two internal dielectric layers 19 and 21. As such, it may occur simultaneously from both sides or singularly, with the substrate inverted following the initial ablation step.

In FIG. 9, each of the continuous holes formed in the FIG. 8 structure are filled with electrically conductive paste 41, preferably one of those mentioned above, e.g., Ablebond “8175”. Paste application may be performed by conventional techniques such as stencil printing, screen printing, doctor blade or injection deposition. In one embodiment, a total of <0.5 grams of paste may be deposited in each of the formed continuous holes. Depending on the particular paste used, drying may occur at this point to remove any residual solvents. Following deposition and drying, if required, excess paste removal (e.g., from the outer surfaces on layers 35) is performed. Notably, the paste 41 engages both the dielectric inner walls of the openings in layers 31 and 33, in addition to the plated material 27 in the interior holes 25.

Following any necessary paste cleaning operation, the next step involves the removal of the remainder of the outer conductive layers 35, as seen in FIG. 10. Such removal may be accomplished by various means, one of the preferred two being to peel away the layers and the other being to etch the metallurgy. In the latter, the substrates in FIG. 9 are exposed to cupric chloride etchant solution which is sprayed onto the opposed sides for a period of from about 0.5 minutes to about 2 minutes. The etchant may be at a temperature of about forty to about fifty degrees C during this operation. The result is the structure of FIG. 10. It is understood that in its simplest form, the structure depicted in FIG. 10 may function as a circuitized substrate. For example, the substrate may include the shown multiple dielectric layers with the “personalized” circuit patterns yet to be added (see below), or simply including the single interim conductive layer 11. In a preferred embodiment, as explained above, the FIG. 10 structure (now referred to as a circuitized substrate 43) is bonded to other circuitized substrates and/or pluralities of individual conductive and dielectric layers to form a multilayered circuitized substrate assembly such as shown in FIG. 11. As such, substrate 43 may serve as a “core” to complement the other substrates in such a multilayered structure, including particularly a power core if layer 11 is to serve as a power plane in the final structure. It may provide this capability even though it does not include conductive circuitry (signal lines) on opposite external surfaces thereof.

In FIG. 11, there is shown a circuitized substrate assembly 51 according to one aspect of the invention. Assembly 51 includes circuitized substrate 43, in addition to second and third circuitized substrates 53 and 55, and may further include additional circuitized substrates if desired. In one example, a total of 11 circuitized substrates may be utilized to form a final circuitized substrate assembly in accordance with the teachings of this invention. The second and third substrates 53 and 55 may be similar in construction to substrate 43 but most preferably are different. Each may include a plurality of layers of dielectric material such as of that described above with alternating layers of conductive material (again, such as that described above) therein. These conductive layers may include signal, ground or power planes of the type typically found in many PCB constructions. Such conductive layers, if signal planes, are also “personalized” (patterned) in accordance with the operational requirements for the finished assembly. Most significantly, the conductive planes 57 and 59 of substrates 53 and 55, respectively, are oriented in a facing relationship to interim substrate 43 such that, when the three substrates are bonded together, these signal layers will in effect be positioned on the corresponding outer dielectric layer (31, 33) of substrate 43. Planes 57 and 59 are understood to represent one of several possible conductive planes within the respective substrates 53 and 55, respectively. Accordingly, using the description that these two conductive layers are positioned on one of the respective dielectric layers 31 and 33 is meant to include the situation where the conductive layers are positioned on the interim sticker or similar dielectric layer (see below) which in turn is bonded directly to one of the two hosting dielectric layers of substrate 43.

The three substrates 43, 53 and 55 are bonded together using a conventional lamination process known in PCB manufacturing. In the present invention, this lamination may occur at a pressure within the range of about 300 PSI to 1000 PSI and at temperatures within the range of about 180 degrees C to about 250 degrees C. Significantly, this lamination process is at sufficient heat and pressure to finally (fully) cure the outer dielectric layers 31 and 33, which prior to this lamination were at the aforementioned “B-stage” cure or similar. The now fully cured (and final thickness) outer dielectric layers are of a precise thickness, which when combined with the previously fully cured dielectric layers 19 and 21, serve to define the precise length of the continuous thru holes between the signal planes 57 and 59. This length, as mentioned also above, is the pre-determined length sufficient to assure that a desired impedance level is attained for signals passing through the continuous thru holes, including the portions having the plating thereon and that without (where only the paste is the conductive medium). The paste within such lengths is also adequate that a relatively low resistivity is present for the signals passing also there-through. These desired impedance and resistivity levels are considered highly desirable to assure the high speed signal capabilities for assembly 51 and other assemblies in which substrates such as substrate 43 are utilized. Of further significance, such capabilities are possible while attaining high density patterns of thru holes. In one example, a total of from about 5,000 to about 10,000 thru holes per square inch may be possible.

Using layers having the dimensions defined above, the impedance levels for each signal path through the continuous, paste-filled thru holes are within the range of from about forty to about sixty ohms. Resistance of less than about one milliohm is possible in each of such thru holes using these materials as well. These values are not meant to limit the broader aspects of this invention, however, as impedance and resistance levels may vary significantly depending on the materials, thicknesses, and other parameters used.

Significantly, the respective quantities of paste 41 have extended outwardly from the continuous thru holes of the interim substrate 43 to partially fill thru holes within the adjacent substrates as a result of the lamination of the three substrates. This is desirable to assure an enhanced connection to these outer thru holes, if utilized. It is understood that such additional thru holes are not necessary, as the lands of the continuous thru holes of interim substrate 43 may contact only signal pads or lines of the outer substrates to form positive connections thereto. It is also within the broader aspects of this invention to eliminate any conductive layers or thru holes and use only the connection between planes 57 and 59.

In the broadest embodiment of the invention, only two circuitized substrates may be utilized to perform a final, bonded assembly 51. As shown in FIG. 11, however, the utilization of a third circuitized substrate is usually desired, as is the addition of still more such substrates. All of this depends of course on the operational requirements of the final multilayered assembly. It is also possible to utilize a conventional sticker sheet between respective pairs of substrates, one being shown between the upper substrate 53 and interim substrate 43 in FIG. 11, while no such sheet is shown between substrate 43 and lower substrate 55.

As seen in FIG. 11, assembly 51 includes outer conductor pads 61 on the upper surface thereof (of the upper substrate 53) and conductor pads 63 on the lower surface thereof (of the lower substrate 55). These pads, preferably copper or copper alloy, may be PTH “lands” as shown or simple pads connected to signal lines which also form part of the upper circuitry on these surfaces. The purpose of each, as is known, is to enable the assembly to be electrically coupled to other structures such as a chip carrier or semiconductor chip (a chip 65 is shown in FIG. 11) and a hosting PCB 67, assembly 51 thus serving as an interconnector between the two. A preferred means of coupling is solder balls 71, which may be of conventional lead-tin solder composition or of the more recent lead free solder compositions. These solder balls are re-flowed to complete the connections with the respective conductors. Understandably, there are conductors on the underside of the chip 65, but these are not shown herein for ease of illustration purposes. Conductors 73, also preferably copper or copper alloy, are shown on the hosting PCB 67, and preferably of conventional construction (e.g., flat pads or PTH lands). As is known, these conductors may include an additional surface finish material such as nickel, gold, silver, palladium, etc.

Thus there has been shown and defined a circuitized substrate assembly comprised of at least two circuitized substrates, one of which includes a plurality of continuous electrically conductive thru holes including a portion thereof which includes plating and conductive paste as the conductive mediums and the other where the paste serves as the only conductive medium. This assembly is particularly designed for interconnecting two electrical structures such as chips onto PCBs or chip carriers onto PCBs but may serve different functions, including as a hosting substrate itself (PCB) for electrical components such as chips or chip carriers. An assembly of the present invention provides significant wiring density increases over conventional printed circuit board constructions and also insures high density thru holes patterns. The present invention enables a facile process and a resulting robust structure, while not requiring complete filling of conductive paste within all thru holes.

While there have been shown and described what are at present the preferred embodiments of the invention, it will be obvious to those skilled in the art that various changes and modifications may be made therein without departing from the scope of the invention as defined by the appended claims.

What is claimed is:

1. A method of making a circuitized substrate comprising:
providing a first conductive circuit layer having first and second sides;
bonding a first dielectric layer having a first thickness to said first side of said conductive circuit layer and a second dielectric layer having a second thickness to said second side of said conductive circuit layer;
forming a first plurality of holes within said first and second dielectric layers, said first plurality of holes extending through said first and second dielectric layers;
bonding third and fourth dielectric layers to said first and second dielectric layers, respectively, such that said first and third dielectric layers will have a combined third thickness and that said second and fourth dielectric layers will have a combined fourth thickness;
forming a second plurality of holes within each of said first, second, third and fourth dielectric layers, each of said second plurality of holes being in alignment with a respective one of said first plurality of holes within said first and second dielectric layers to thereby form a plurality of continuous holes through said first, second, third and fourth dielectric layers; and
positioning a quantity of conductive paste within each of said continuous holes to thereby form a plurality of continuous thru-holes each having a length such that said conductive paste within each of said thru-holes will possess a relatively low resistivity.

2. The method of claim 1 further including forming a conductive layer on each of said first plurality of holes within said first and second dielectric layers prior to said bonding of said third and fourth dielectric layers to said first and second dielectric layers, respectively.

3. The method of claim 2 wherein said forming of said conductive layer on said first plurality of holes is accomplished using an electroplating operation.

4. The method of claim 1 wherein said forming of said conductive circuit on said first dielectric layer is accomplished using photolithographic processing.

5. The method of claim 4 wherein said first conductive circuit is formed as a power plane.

6. The method of claim 1 wherein said bonding of said third and fourth dielectric layers to said first and second dielectric layers, respectively, is accomplished while said third and fourth dielectric layers are in a partially cured state.

7. The method of claim 1 wherein said positioning of said quantity of conductive paste within each of said continuous holes is accomplished using a step selected from the group of steps consisting of stencil printing, screen printing, doctor blade or injection deposition.

8. The method of claim 1 wherein said forming of said first plurality of holes within said first and second dielectric layers and extending through said first and second dielectric layers is accomplished using laser or mechanical drilling.

9. The method of claim 1 wherein said forming of said second plurality of holes within said first, second, third and fourth dielectric layers in alignment with a respective one of said first plurality of holes within said first and second dielectric layers to thereby form a plurality of continuous holes through said first, second, third and fourth dielectric layers is accomplished using laser or mechanical drilling.

10. The method of claim 1 further including bonding said circuitized substrate to at least one other circuitized substrate to form a circuitized substrate assembly.

11. The method of claim 10 wherein said bonding of said circuitized substrate to said at least one other circuitized substrate to form a circuitized substrate assembly is accomplished using a lamination process.

12. The method of claim 10 further including electrically coupling at least one electrical component to said circuitized substrate assembly.

13. A circuitized substrate comprising:
a first dielectric layer having a first thickness;
a conductive circuit positioned on said first dielectric layer;
a second dielectric layer having a second thickness bonded to said conductive circuit;
a first plurality of holes extending through said first and second dielectric layers and including an electrically conductive layer thereon;
third and fourth dielectric layers bonded to said first and second dielectric layers, respectively;
a plurality of continuous thru holes extending through said first, second third and fourth dielectric layers, each of said plurality of continuous thru holes being in alignment with a respective one of said first plurality of holes within said first and second dielectric layers and including a quantity of electrically conductive paste therein, said electrically conductive paste possessing a relatively low resistivity.

14. The circuitized substrate of claim 13 wherein said first and second dielectric layers are each comprised of a low dielectric constant, low dielectric loss material.

15. The circuitized substrate of claim 13 wherein said conductive circuit on said first dielectric layer comprises a power plane.

16. The circuitized substrate of claim 13 wherein said electrically conductive layer on said first plurality of holes is comprised of copper or copper alloy.

17. The circuitized substrate of claim 13 wherein said third and fourth dielectric layers bonded to said first and second dielectric layers are each comprised of a low dielectric constant, low dielectric loss material.

18. The circuitized substrate of claim 13 further including a second circuitized substrate bonded thereto, said circuitized substrate and said second circuitized substrate forming a circuitized substrate assembly.

19. The invention of claim 18 further including at least one electrical component electrically coupled to said circuitized substrate assembly.

20. The invention of claim 19 wherein said at least one electrical component comprises a semiconductor chip.
